(19) United States
(12) Patent Application Publication
(10) Pub. No.: US 2021/0123431 A1
(43) Pub. Date: Apr. 29, 2021

(54) SYNTHETIC DATA GENERATION SYSTEMS AND METHODS

(71) Applicant: HALLIBURTON ENERGY SERVICES, INC., Houston, TX (US)

(72) Inventors: Mikko JAASKELAINEN, Katy, TX (US); Ronald Glen DUSTERHOFT, Katy, TX (US); Stanley V. STEPHENSON, Duncan, OK (US)

(73) Assignee: HALLIBURTON ENERGY SERVICES, INC., Houston, TX (US)

(21) Appl. No.: 16/664,184

(22) Filed: Oct. 25, 2019

(51) Int. Cl. F04B 49/06; G05B 13/04; G05B 13/02; F04B 47/00

(52) U.S. Cl. CPC F04B 49/065; F04B 47/00; G05B 13/0265; G05B 13/041

(57) ABSTRACT

A data synthesis model generates synthetic sensor values for managing a well by an AI system. The data synthesis model is generated and trained using downhole sensor data and input variable data for an electric frac pump. The trained data synthesis model is executed by a well to generate a synthetic data value based on sensor data from the well and respective electric frac pump control values. A well AI system uses the generated synthetic data value, sensor data, and respective electric frac pump control values to determine adjustments to the electric frac pump.

### TECHNICAL FIELD

The present technology pertains to data synthesis. In particular, the present technology pertains to generating models for synthesizing data to be used by upstream models in the oil and gas industry.

### BACKGROUND

In the oil and gas industry, drilling is often done with the assistance of artificial intelligence systems such as expert systems, downhole environment simulations, downhole environment and/or well characteristic prediction models, and the like. Generally, the artificial intelligence systems base outputs (e.g., pump commands, etc.) on sensor and state data from downhole sensors and/or pumps, respectively. In many cases, a well may not be tooled with sensors for generating sensor data needed and/or useful to the artificial intelligence systems. As a result, artificial intelligence systems may be unable to generate useful outputs or the generated outputs may be inferior in comparison to the case where additional sensor data were available.

It is with these observations in mind, among others, that aspects of the present disclosure were concerned and developed.

### BRIEF DESCRIPTION OF THE DRAWINGS

The embodiments herein may be better understood by referring to the following description in conjunction with the accompanying drawings in which like reference numerals indicate analogous, identical, or functionally similar elements. Understanding that these drawings depict only exemplary embodiments of the disclosure and are not therefore to be considered to be limiting of its scope, the principles herein are described and explained with additional specificity and detail through the use of the accompanying drawings in which:

FIG. 1A is a schematic view of a downhole electric frac pump and environment, according to various embodiments of the subject technology;

FIG. 1B is diagrammatic view of a surface electric frac pump and environment, according to various embodiments of the subject technology;

FIG. 2 is a schematic diagram of an example conveyance drilling environment, according to various embodiments of the subject technology;

FIG. 3 is a block diagram of a data synthesis model training system and environment, according to various embodiments of the subject technology;

FIG. 4 is a block diagram of a system and environment for executing a data synthesis model, according to various embodiments of the subject technology;

FIG. 5 is a flowchart depicting a method for generating a data synthesis model, according to various embodiments of the subject technology;

FIG. 6 is a flowchart depicting a method for executing a trained data synthesis model, according to various embodiments of the subject technology; and

FIG. 7 is a system diagram illustrating a computing system, in accordance with various embodiments of the subject technology.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

It should be understood at the outset that although illustrative implementations of one or more embodiments are illustrated below, the disclosed compositions and methods may be implemented using any number of techniques. The disclosure should in no way be limited to the illustrative implementations, drawings, and techniques illustrated herein, but may be modified within the scope of the appended claims along with their full scope of equivalents.

This disclosure provides techniques for generating data synthesis models for use by upstream services, such as downhole environment prediction models, tool controller systems, and drilling/pumping platform monitoring, etc. The data synthesis models can be trained using historical downhole sensing data and/or data retrieved from monitored off-set wells such as, for example and without imputing limitation, downhole pressure, distributed fiber optic sensors, log files, microseismic data, microdeformation data, etc.

In particular, artificial intelligence may be used to predict downhole responses or determine controller variables for a frac pump based on downhole and/or surface responses to pump settings. The responses can be detected via downhole sensors, surface sensors, or some combination. In many cases, certain sensor data may be unavailable and a synthetic data model can be used to generate the unavailable sensor data for use by the artificial intelligence to predict downhole responses or determine controller variables, etc. In at least one aspect, data synthesized by the synthetic data model can be used as a surrogate for otherwise missing downhole data measurements.

In one example, in order to produce synthetic data for downstream usage (e.g., at a well lacking various sensors), the synthetic data model can be generated at a laboratory well. A laboratory well may be a well or pad instrumented with downhole sensors such as, for example and without imputing limitation, frequency-limited pressure sensors, distributed fiber optic temperature sensors, strain sensors, acoustic measurement sensors, microseismic sensors, and microdeformation sensors. Input variables (e.g., pressure, rate, chemical concentration, proppant rates, proppant ramp rates, and/or diversion drops in frequency and/or mass, etc.) can be varied at the laboratory well and frequency-limited data (e.g., from deployed sensors) can be collected and used to generate a rich data set. In some examples, frequency-limited data includes data for frequencies between 0.01 Hz and 10,000 Hz.

Additionally, the input variables can be varied over a range of expected responses to train one or more synthetic data models. In some examples, substantially similar approaches can be undertaken in wells tooled with fewer and/or more limited sensors in order to generate a more robust (e.g., generalizable, etc.) data set. In some examples, the one or more synthetic data models can be further tuned at deployment to active treatment fracturing wells by executing a tuning sequence at various stages of the active treatment fracturing well. In effect, the synthetic data model can be updated on a case-by-case basis in order to specialize the deployed synthetic data model to a respective borehole and well environment to which it is deployed. Likewise, a substantially similar approach can be applied to multi-well cases such as, for example and without imputing limitation, zipper fracture wells where formations for each respective well may be similar and thus a transfer learning approach between respective borehole environments can accelerate tuning of respective synthetic data models.

Further, electrical fracturing equipment (e.g., electrical frac pumps, etc.) may be precisely controlled in order to generate specific time series variations in input variables. As a result, difference response characteristics can be targeted for training the synthetic data model. For example, abrupt changes in rate or pressure, which may cause reflections from perforations and/or frac plug locations or from fracture properties (e.g., length, etc.) can be simulated and, as a result, included in training the synthetic data model. While the pump described here is an electrical frac pump, with other kinds of frac pumps may be used, such as diesel or natural gas frac pumps, without departing from the spirit and scope of this disclosure.

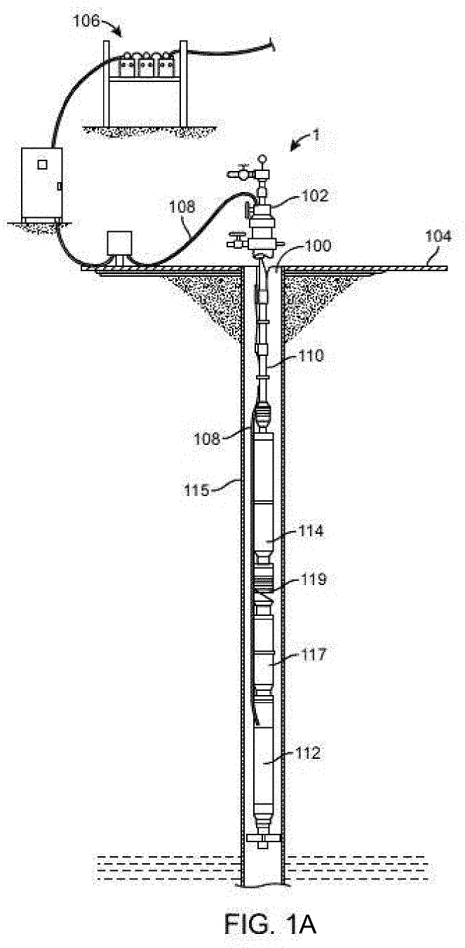

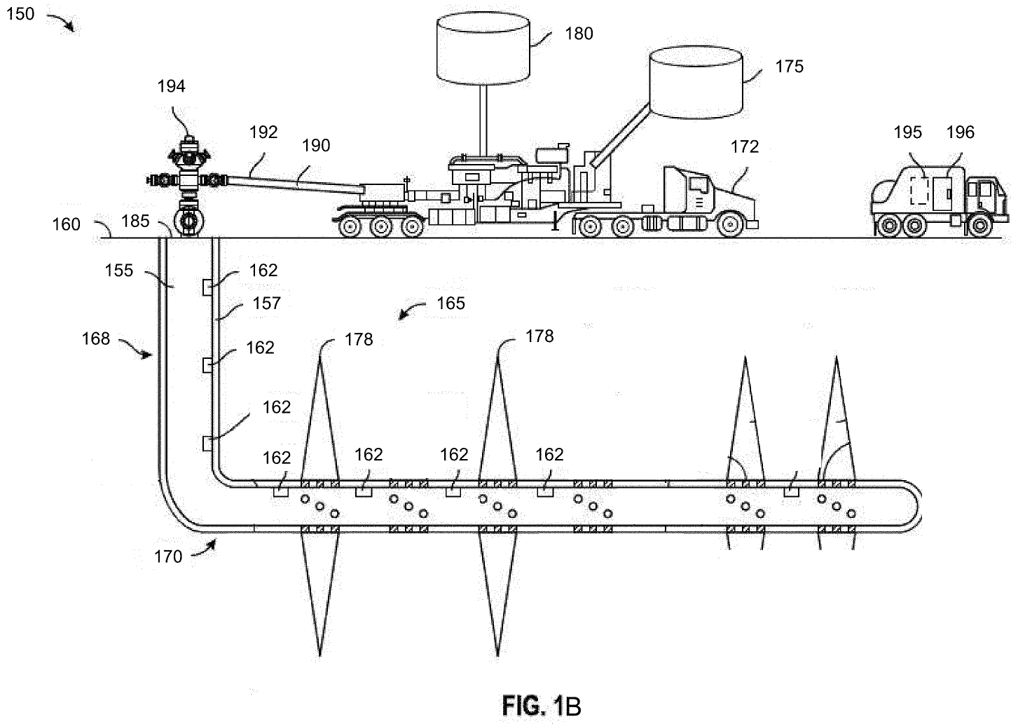

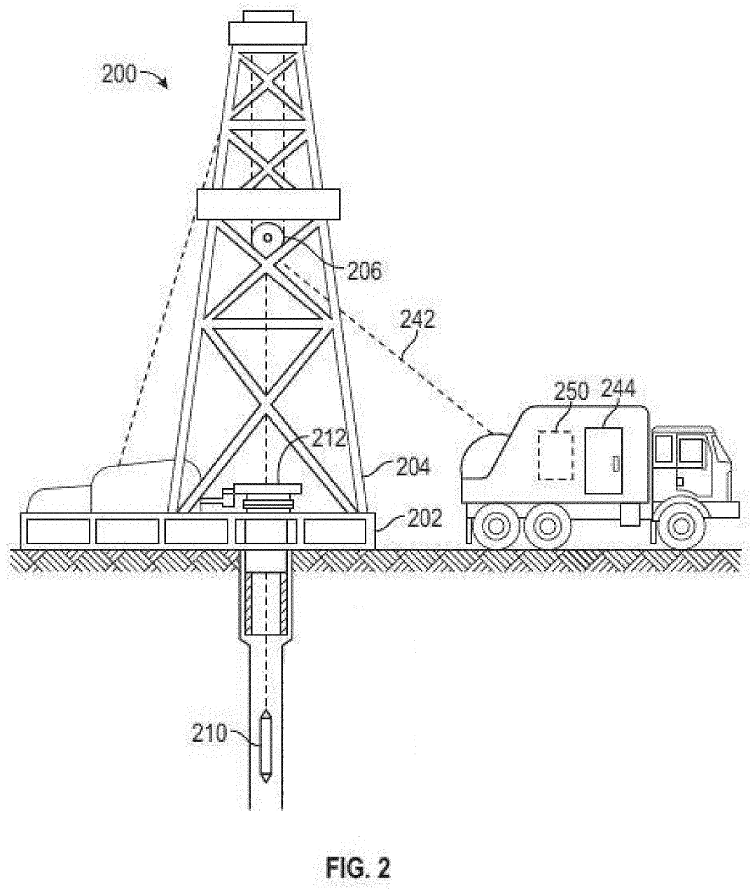

The disclosure now turns to discussion of various figures for further clarity of explanation. FIGS. 1A, 1B, and 2 respectively depict various environments in which the apparatuses, systems, and methods of the disclosure may be implemented. It is understood that elements and/or steps of the figures depicted may be added, removed, and/or modified without departing from the spirit and scope of the disclosure. Accordingly, the figures are provided for explanatory purposes only and a person of ordinary skill in the art with the benefit of this disclosure may implement and modify the apparatuses, systems, and methods disclosed herein without departing from the spirit and scope of the disclosure.

FIG. 1A depicts an example of a wellbore pumping system 1 in which the apparatuses, systems, and methods of this disclosure may be deployed. The system 1 includes a wellbore 100 having a wellhead 102 at the surface 104. The wellbore 100 extends and penetrates various earth strata including hydrocarbon containing formations. A casing 115 can be cemented along a length of the wellbore 100. A power source 106 can have an electrical cable 108, or multiple electrical cables, extending into the wellbore 100 and coupled with a motor 112. It should be noted that while FIG. 1 generally depicts a land-based operation, those skilled in the art will readily recognize that the principles described herein are equally applicable to subsea operations that employ floating or sea-based platforms and rigs, without departing from the scope of the disclosure. Also, even though FIG. 1 depicts a vertical wellbore, the present disclosure is equally well-suited for use in wellbores having other orientations, including horizontal wellbores, slanted wellbores, multilateral wellbores or the like.

Disposed within the wellbore 100 can be a tubing string 110 having an electric pump 114 forming an electric pump string. The electric pump 114 may be driven by a motor 112. The tubing string 110 can also include a pump intake 119 for withdrawing fluid from the wellbore 100. The pump intake 119, or pump admission, can separate the fluid and gas from the withdrawn hydrocarbons and direct the fluid into the electric pump 114. A protector 117 can be provided between the motor 112 and the pump intake 119 to prevent entrance of fluids into the motor 112 from the wellbore. The tubing string 110 can be a series of tubing sections, coiled tubing, or other conveyance for providing a passageway for fluids. The motor 112 can be electrically coupled with the power source 106 by the electrical cable 108. The motor 112 can be disposed below the electric pump 114 within the wellbore 100. The electric pump 114 can provide artificial pressure, or lift, within the wellbore 100 to increase the withdrawal of hydrocarbons, and/or other wellbore fluids. The electric pump 114 can provide energy to the fluid flow from the well thereby increasing the flow rate within the wellbore 100 toward the wellhead 102.

FIG. 1B is a schematic view of a wellbore operating environment 150 in which apparatuses, systems, and methods as disclosed herein may be deployed. As depicted, a wellbore 155 extends from the surface 160 of the earth through the formation 165 formed by a drilling device from a previous drilling operation (not shown). The wellbore 155 has a vertical segment 168 as well as horizontal segment 170. The wellbore 155 has a casing 157 extending along its length and which may be cemented to the inner surface of the wellbore 155. A plurality of sensors 162 may be provided along the length of the wellbore to detect temperature, pressure, strain, vibration, or flow rate. The plurality of sensors 162 may include for instance pressure or temperature transducers, or may include point and distributed fiber optic sensors. As discussed further below, sensors 162 may be used to generate and execute a data synthesis model. As further illustrated, pump equipment 172 is provided in the form of a truck carrying a pump is provided on the surface 160. While a truck is shown, the pump equipment 172 can be in any form, such as a standalone unit, a plurality of pump units, within a vehicle or outside a vehicle, or integrated with a vehicle, and may be on the surface 160 or partially inserted into the wellbore 155. The pump equipment may be electrical pumps, or hydraulic pumps, or pumps capable of quick adjustment of flow rate. A carrier fluid 175 is provided which may be mixed or blended with, for example, a proppant 180 and pumped by the pump equipment 172 to form a treatment fluid 190. The treatment fluid 190 may be pumped through line 192 into the entrance 185 of the wellbore 155 via fracturing tree 194. The fracturing tree 194 includes various inlets and valves necessary for various fluids, including diversion treatment fluid 140. While the treatment fluid 190 is pumped into the wellbore 155 through the casing 157, in other embodiments, additional tubing, such as coiled tubing, can be inserted within the casing 157 to inject or place the carrier fluid 175 and proppant 180.

In general, the carrier fluid 175 may be continuously pumped into the wellbore 155. The proppant 180 can be introduced periodically into the carrier fluid 175 as a small volume, concentration, or mass. The proppant 180 may be in fluid form or may be a solid, or a semi-solid, a gel, and may be in the form of a particulate, and may be degradable. The proppant 180 may be referred to as a having a concentration (e.g., a concentration of solid, semi-solid) or a mass with the carrier fluid 175 or treatment fluid 190. Further, the proppant 180 may have a flow rate which may be the same or different than the carrier fluid 175 depending on the relative form and density of the proppant 180 and the carrier fluid 175.

A processing facility 196 having a computer system 195 may be provided at the surface 160 for collecting, storing or processing data related to the wellbore operating environment 150. The processing facility may be communicatively coupled, via wire or wirelessly, with the pump equipment 172. The pump equipment 172 may have controls or be controlled by the processing facility 196 including flow rates of the carrier fluid 175, proppant 180, and treatment fluid 190, as well as obtaining data related to flow rates, proppant rates, diversion materials, and chemicals. Additional data may be obtained regarding the wellbore 155, including flow rate distribution wellbore flow distribution of fluid into fractures 178 in the wellbore 155, including temperature and/or pressure distributions throughout the wellbore 155, which may be obtained by the sensors 162 positioned along the length of the casing 157 to detect, for example and without imputing limitation, pressure, temperature, strain (e.g., permanent rock deformation, etc.), vibration (e.g., seismic data produced by a surface vibrator, etc.), and/or flow rates along the length of the wellbore 155.

FIG. 2 illustrates a diagrammatic view of a conveyance logging (WL) borehole operating environment 200 (also referred to as “wireline” in the field) in which aspects of the present disclosure can be implemented. A hoist 206 can be included as a portion of a platform 202 which is coupled to a derrick 204. The hoist 206 may be used to raise or lower equipment such as tool 210 into or out of a borehole, where the borehole may be a monitoring well where response parameters may be measured in response to changes in flow rate, proppant concentration, diversion concentration, or a treatment well. A conveyance 242 provides a communicative coupling between tool 210 and a facility 244 at the surface. Conveyance 242 may be a tubular conveyance such as coiled tubing, joint tubing, or other tubulars, and may include wires (one or more wires), slicklines, cables, or the like, as well as a downhole tractor. Additionally, power can be supplied via the conveyance 242 to meet power requirements of the tool. Conveyance 242 may include optical fibers that may be used for communication or distributed fiber optic sensing where the full length of conveyance 242 may act as a distributed sensor. The distributed sensor may be used to measure temperature, acoustics, vibration and strain, etc. Tool 210 may have a local power supply, such as batteries, downhole generator and the like. When employing non-conductive cable, coiled tubing, pipe string, or downhole tractor, communication may be supported using, for example, wireless protocols (e.g., EM, acoustic, etc.), and/or measurements and logging data can be stored in local memory for subsequent retrieval. Facility 244 may include a computing device 250 able to communicate with the devices and systems of the present disclosure.

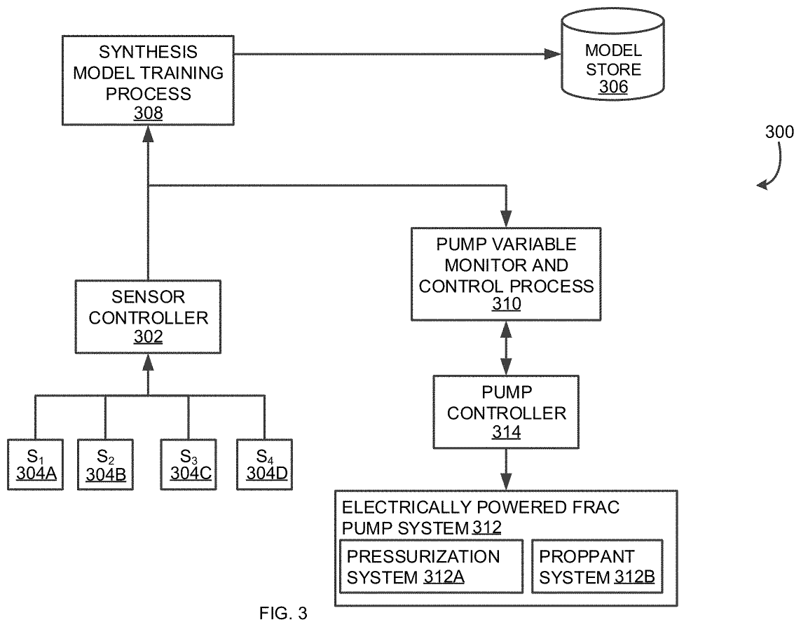

FIG. 3 is a block diagram illustrating a system 300 for generating a data synthesis model that can itself generate synthetic, or simulated, sensor data values. For example, a well environment may not be tooled with a particular sensor which otherwise generates output used by an expert system or other artificial intelligence system (e.g., probabilistic, rules-based, or some combination of the two) for managing electric frac pumps or predicting a downhole environment. The system 300 may generate a data synthesis model that can be utilized in such a case to generate synthetic data values of the particular sensor and so provide the expert system or other artificial intelligence system a more robust set of features (e.g., sensor data) with which to make frac control decisions or predict downhole environment characteristics.

A sensor controller 302 receives sensor data from a set of sensors 304A-D. Sensors 304A-D may each be different sensor devices. As an example, and without imputing limitation, sensor 304A may be a fiber optic temperature sensor, sensor 304B may be an acoustic logging tool, sensor 304C may be a vibration sensor, and sensor 304D may be a microseismic sensor. Various other sensors may be used, as will be understood by a person having ordinary skill in the art, and the referenced sensors are for explanatory purposes and should not be taken as limiting the disclosure to only the listed sensors. Data gathered by Sensors 304A-D may include surface and subsurface distributed production data, using distributed fiber optics to do production allocation along the wellbore and using temperature and/or acoustics to determine inflow points, fluid types, or volumes. They may further include measurements of temperature, flow, dynamic and/or static strain, acoustic intensity, acoustic phase, resistivity, electromagnetic signals, and frequency, amplitude, or phase of any of the signals.

A synthesis model training process 308 receives sensor data from the sensors 304A-D via sensor control 302 as well as pump control information from a pump variable monitor and control process 310. The pump monitor and control process 310 may relay input variables (e.g., commands) from synthesis model training process 308 to a pump controller 314 and likewise relay pump component information from an electrically powered frac pump system 312 to the synthesis model training process 308. Electrically powered frac pump system 312 may include, for example and without imputing limitation, a pressurization system 312A and a proppant system 312B. Pressurization system 312A may be responsible for pressure settings of the pump for pumping fluid into a borehole. Proppant system 312B may be responsible for proppant settings of the pump such as, for example, proppant volume, mass, etc. Various other systems, subsystems, and components may be included in electrically powered frac pump system 312, however this disclosure focuses on pressurization system 312A and proppant system 312B for the sake of clarity and explanation. Generally, pump controller 314 may send commands to, and/or adjust settings of, pressurization system 312A and proppant system 3128.

Synthesis data model training process 308 may receive the input variable and sensor data from pump variable monitor and control process 310 and sensor controller 302 respectively to generate a data synthesis model that can simulate and/or predict a sensor value (e.g., a value of microseismic sensor 304D, etc.) based on other sensor values (e.g., values of sensors 304A-C, etc.) and/or the input variables. Various training methodologies may be applied by synthesis data model training process 308 for training one or more models such as, for example and without imputing limitations, rules-based updates, back propagation, equilibrium propagation, a combination of methods, and the like. Likewise, various machine learning models may be trained by synthesis model training process 308 such as, for example and without imputing limitation, regression models (e.g., probit, logit, linear, polynomial, etc.), neural networks (e.g., deep learning networks, recurrent networks, convolutional networks, memory-based networks, attention-based networks, etc.), Markov models, rules-based systems, or some combination, etc.

Nevertheless, synthesis model training process 308 may modify pump variables (e.g., over a time series plan, etc.) for training a respective model or models by sending commands to pump variable monitor and control process 310. Once a data synthesis model has been generated and trained, synthesis model training process 308 may store the data synthesis model in a model store 306 for later retrieval and use. Data store 306 may be a local database, remote server, cloud storage solution, or the like. In some examples, data synthesis models may be stored in association with one or more accounts (e.g., tenants, users, clients, etc.), which may access the stored data synthesis models via a credentialing and/or authentication process or the like.

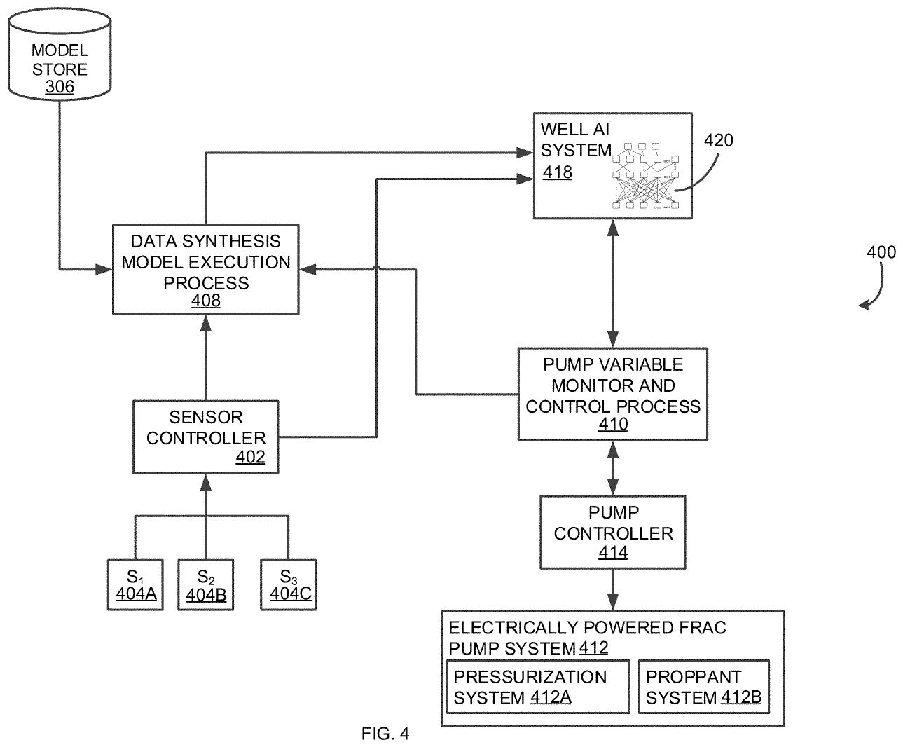

FIG. 4 is a block diagram illustrating a system 400 for using a data synthesis model to control an electrically powered frac pump system 412. The data synthesis model may be generated at an earlier time by, for example, system 300 discussed above. In some examples, the data synthesis model may be associated with a particular user or may be a general model provided to the user in the field or the like.

Here, the data synthesis model is retrieved from model store 306 by a data synthesis model execution process 408. In general, data synthesis model execution process 408 receives a data synthesis model for generating one or more synthetic sensor values based on received data from deployed sensors. Data synthesis model execution process 408 executes the received data synthesis model to generate (e.g., simulate, predict, etc.) a sensor value, which is provided to downstream processes discussed below.

Data gathered by Sensors 402A-C may include surface and subsurface distributed production data, using distributed fiber optics to do production allocation along the wellbore and using temperature and/or acoustics to determine inflow points, fluid types, or volumes. They may further include measurements of temperature, flow, dynamic and/or static strain, acoustic intensity, acoustic phase, resistivity, electromagnetic signals, and frequency, amplitude, or phase of any of the signals.

Data synthesis model execution process 408 receives sensor data from a sensor controller 402 which receives sensor data from sensors 404A-C. Sensors 404A-C may be, for example and without imputing limitation, a fiber optic temperature sensor, an acoustic logging tool, and a vibration sensor substantially similar to sensors 304A-C discussed above. Notably, sensors 404A-C do not include a microseismic sensor (e.g., 304D). Sensor data values corresponding to a microseismic sensor may be generated by data synthesis model execution process 408 executing the received data synthesis model based on data values from sensors 404A-C. Further, data synthesis model execution process 408 may receive input variable data from a pump variable monitor and control process 410, which may also be used by the received data synthesis model 408 in conjunction with the sensor data values from sensors 404A-C to generate a synthetic microseismic sensor data value.

Data synthesis model execution process 408 can provide the generated synthetic sensor data value to a well artificial intelligence (AI) system 418. Well AI system 418 may include rules for controlling electrically powered frac pump system 412 based on various sensor and input variable data. For example, well AI system 418 can include a trained model 420 for predicting various aspects of a downhole environment, such as formation characteristics, fracture characteristics, stage status, etc. In some examples, well AI system 418 may adjust electrically powered frac pump system 412 based on the predicted downhole environment aspects, such as adjusting pressure, flow rate, proppant mix, etc.

In particular, trained model 420 may generate predictions based on, for example and without imputing limitation, fiber optic temperature sensor data, acoustic logging tool data, vibration sensor data, and microseismic sensor data. Here, where sensors 404A-C do not include microseismic sensor data, trained model 420 receives the synthetic microseismic sensor data, generated by data synthesis model execution process 408, alongside sensor data for sensors 404A-C from sensor controller 402. Based on the received real and synthetic sensor data and input variable data received from pump variable monitor and control process 410, well AI system 418 sends commands to pump controller 414, which in turn executes said commands via pressurization system 412A and/or proppant system 412B.

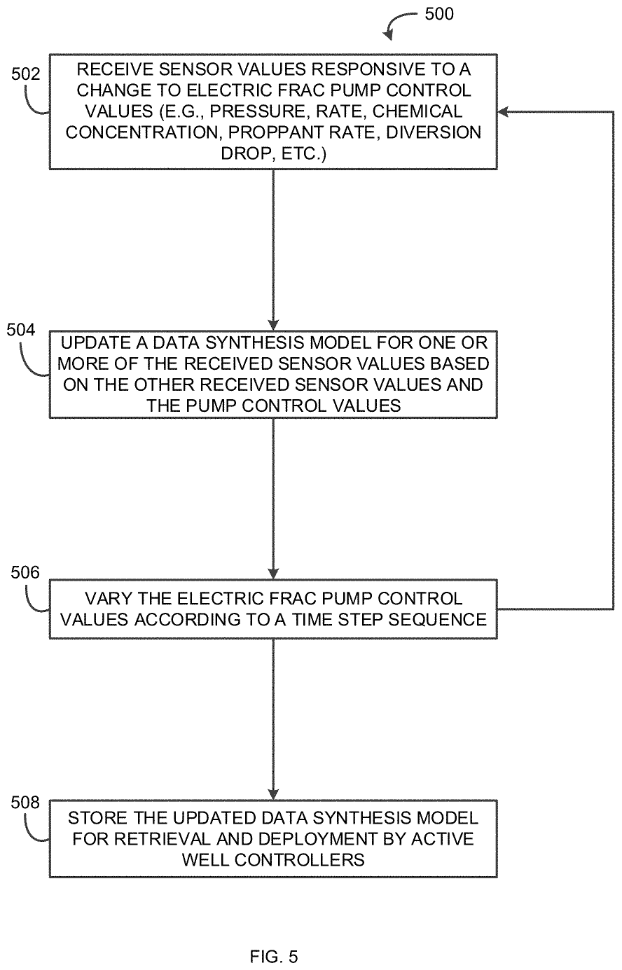

FIG. 5 is a method 500 for generating a data synthesis model. Method 500 may be performed, in whole or part, by a system substantially similar to system 300 discussed above. At step 502, sensor values are received. In particular, the received sensor values are responsive to a change to electric frac pump control values such as, for example and without imputing limitation, pressure, rate, chemical concentration, proppant rate, diversion drop, etc.

At step 504, a data synthesis model is updated for one or more of the received sensor values. The update is based on the other received sensor values and the pump control values. In other words, the data synthesis model performs a training loop (e.g., back propagation, equilibrium propagation, etc.) to update a synthetic data model.

At step 506, the electric frac pump control values are varied according to a time step sequence. In some examples, the variance may be predetermined according to a provided time step sequence. In other examples, the variance may be determined on the fly based on, for example, a stochastic process or the like. While still undergoing training, method 500 may return to step 502 following step 506 to further update (e.g., train) the data synthesis model. Where training is complete, or it is intended to store a version of the data synthesis model (e.g., as part of version control or backup protocols, etc.), method 500 may continue to step 508. Additionally, in some examples, method 500 may both loop to step 502 and continue to step 508.

At step 508, the updated data synthesis model is stored (e.g., in data store 306 discussed above) for later retrieval. The stored model may be retrieved for further updates or deployment by active well controllers. For example, data synthesis model execution process 408, discussed above, may retrieve the stored model to generate synthetic data values for well AI system 418, discussed above.

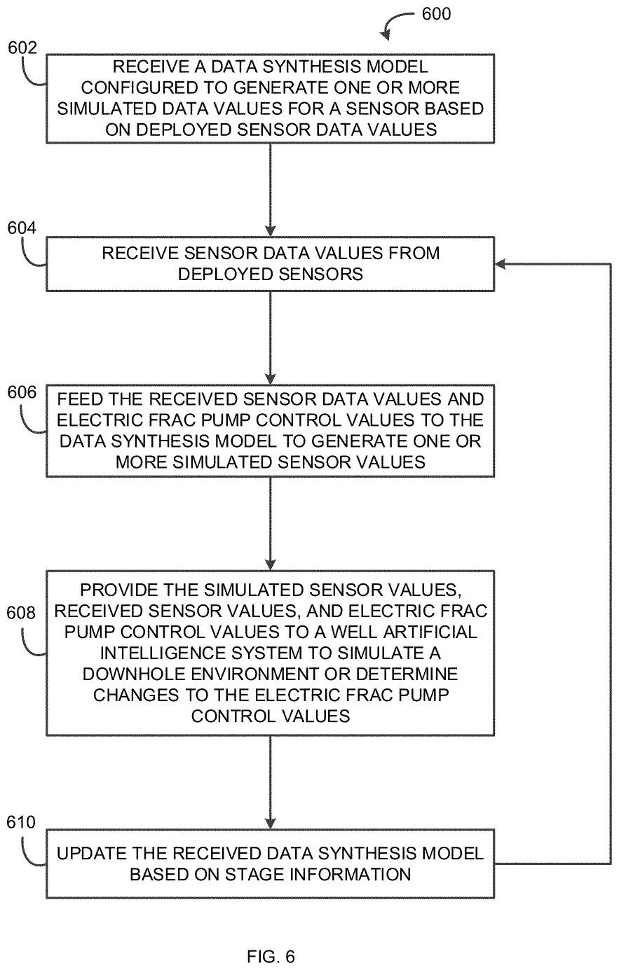

FIG. 6 is a method 600 for executing a data synthesis model, such as the generated and stored by method 500 discussed above. Method 600 may be performed, in whole or part, by a system substantially similar to system 400 discussed above. At step 602, a data synthesis model is received (e.g., from data store 306). The data synthesis model is configured to generate one or more simulated data values for a sensor based on deployed sensor data values.

At step 604, sensor data values are received from deployed sensors. For example, sensors 404A-C, discussed above, may provide sensor data values for generating a simulated data value corresponding to sensor 304D, discussed above. At step 606, the received sensor data values and electric frac pump control values are fed to the data synthesis model to generate one or more simulated sensor values (e.g., a simulated sensor 304D value).

At step 608, the simulated sensor values, received sensor values, and electric frac pump control values are provided to a well artificial intelligence system to simulate a downhole environment or determine changes to the electric frac pump control values. In some examples, the well artificial intelligence system determines changes to the electric frac pump control values based on the simulated downhole environment.

At 610, the received data synthesis model can be updated based on stage information. In particular, method 600 may then loop to step 604 to receive updated sensor values. As a result, the data synthesis model can continue training even in the live environment.

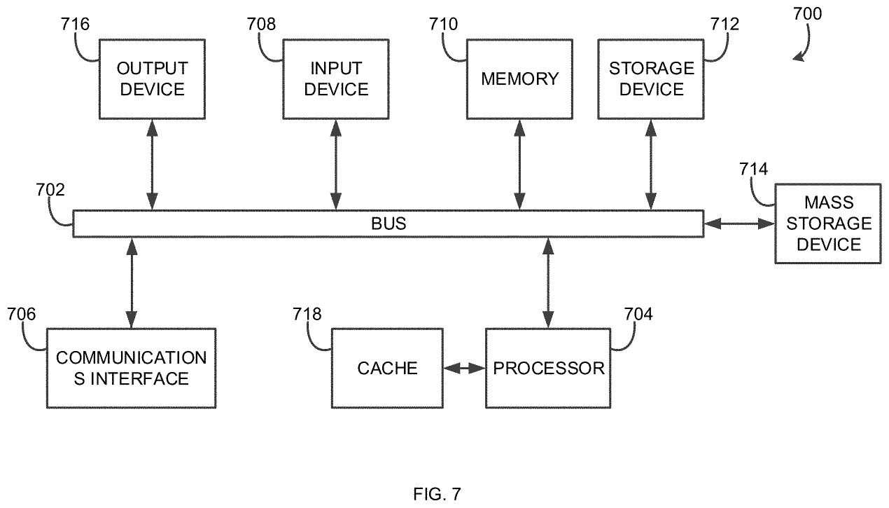

FIG. 7 is a schematic diagram of a computing system 700 that may implement various systems and methods discussed herein. The computing system 700 includes one or more computing components in communication via a bus 702. In one embodiment, the computing system 700 may include one or more processes 704. The processor 704 can include one or more internal levels of cache 718 and a bus controller or bus interface unit to direct interaction with the bus 702. The processor 704 can specifically implement the various methods discussed herein. Memory 710 may include one or more memory cards and a control circuit, or other forms of removable memory, and can store various software applications including computer executable instructions, that when run on the processor 704 implement the methods and systems set out herein. Other forms of memory, such as a storage device 712 and a mass storage device 714, can also be included and accessible by the processor (or processors) 704 via the bus 702. The storage device 712 and mass storage device 714 can each contain any or all of the methods and systems, in whole or in part, discussed herein. In some examples, the storage device 712 or the mass storage device 714 can provide a database or repository in order to store data as discussed below.

The computing system 700 can further include a communications interface 706 by way of which the computing system 700 can connect to networks and receive data useful in executing the methods and systems set out herein as well as transmitting information to other devices. The computer system 700 can also include an input device 708 by which information is input. Input device 708 can be a scanner, keyboard, and/or other input devices as will be apparent to a person of ordinary skill in the art. The system set forth in FIG. 7 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Numerous examples are provided herein to enhance understanding of the present disclosure. A specific set of statements are provided as follows:

Statement 1: A computer-implemented method for generating a data synthesis model includes receiving one or more downhole sensor values from one or more downhole sensors in response to a change in pump control variables including one or more of a surface pressure value, a pump rate value, a chemical concentration value, a proppant rate value, a proppant ramp rate value, a diversion drop frequency value, or a diversion drop mass value, generating a data synthesis model configured to generate predicted values including one or more of the one or more downhole sensor values based on one or more other sensor data values of the one or more downhole sensor values and the pump control variables, and providing the predicted values generated by the data synthesis model to one of a frac pump controller or a downhole environment model configured to simulate a downhole environment based on sensor data.

Statement 2: The method of the preceding Statement may further include the frac pump controller receiving the predicted values, and adjusting, based at least in part on the predicted values, a power supply level for an electric fracturing pump, the power supply level determining one or more parameters comprising flow rate, viscosity, or volume of a material pumped into at least one treatment fracturing well.

Statement 3: The method any of the preceding Statements may further include the one or more downhole sensor values being received from sensors deployed in a laboratory well, the sensors including one or more of a frequency-limited pressure sensor, a distributed fiber optic temperature sensor, a strain sensor, an acoustic sensor, a microseismic sensor, or a microdeformation sensor.

Statement 4: The method of any of the preceding Statements may further include feeding training data into a supervised learning process and changing the pump control variables over a range of expected responses.

Statement 5: The method of the preceding Statement 4 may include the training data including frequency-limited data.

Statement 6: The method of any of the preceding Statements may include the predicted values being provided to one of a frac pump controller or a downhole environment model at a later stage of a treatment fracturing well, and the one or more downhole sensor values being received from sensors deployed to the treatment fracturing well and at an earlier stage of the treatment fracturing well.

Statement 7: The method of any of the preceding Statements may further include applying the data synthesis model to one or more additional treatment fracturing wells, the data synthesis model generating additional synthetic sensor data values based on additional treatment fracturing well sensor data values, and adjusting, based on the additional synthetic sensor data values, one or more additional power supplies for one or more additional fracturing pumps.

Statement 8: A system for generating a data synthesis model includes one or more processors, and a memory including instructions for the one or more processors to receive one or more downhole sensor values from one or more downhole sensors in response to a change in pump control variables including one or more of a surface pressure value, a pump rate value, a chemical concentration value, a proppant rate value, a proppant ramp rate value, a diversion drop frequency value, or a diversion drop mass value, generate a data synthesis model configured to generate predicted values including one or more of the one or more downhole sensor values based on one or more other sensor data values of the one or more downhole sensor values and the pump control variables, and provide the predicted values generated by the data synthesis model to one of a frac pump controller or a downhole environment model configured to simulate a downhole environment based on sensor data.

Statement 9: The system of preceding Statement 8 may include the frac pump controller receiving the predicted values, and the memory further including instructions to adjust, based at least in part on the predicted values, a power supply level for an electric fracturing pump, the power supply level determining one or more parameters including flow rate, viscosity, or volume of a material pumped into at least one treatment fracturing well.

Statement 10: The system of any of preceding Statements 8-9 may include the one or more downhole sensor values being received from sensors deployed in a laboratory well, the sensors including one or more of a frequency-limited pressure sensor, a distributed fiber optic temperature sensor, a strain sensor, an acoustic sensor, a microseismic sensor, or a microdeformation sensor.

Statement 11: The system of any of preceding Statements 8-10 may include the memory further including instructions to feed training data into a supervised learning process and change the pump control variables over a range of expected responses.

Statement 12: The system of preceding Statement 11 may include the training data including frequency-limited data.

Statement 13: The system of any of preceding Statements 8-12 may include the predicted values being provided to one of a frac pump controller or a downhole environment model at a later stage of a treatment fracturing well, and the one or more downhole sensor values being received from sensors deployed to the treatment fracturing well and at an earlier stage of the treatment fracturing well.

Statement 14: The system of any of preceding Statements 8-13 may include the memory further including instructions to apply the data synthesis model to one or more additional treatment fracturing wells, the data synthesis model generating additional synthetic sensor data values based on additional treatment fracturing well sensor data values, and adjust, based on the additional synthetic sensor data values, one or more additional power supplies for one or more additional fracturing pumps.

Statement 15: A non-transitory computer readable medium stores instructions that, when executed by one or more processors, cause the one or more processors to receive one or more downhole sensor values from one or more downhole sensors in response to a change in pump control variables including one or more of a surface pressure value, a pump rate value, a chemical concentration value, a proppant rate value, a proppant ramp rate value, a diversion drop frequency value, or a diversion drop mass value, generate a data synthesis model configured to generate predicted values including one or more of the one or more downhole sensor values based on one or more other sensor data values of the one or more downhole sensor values and the pump control variables, and provide the predicted values generated by the data synthesis model to one of a frac pump controller or a downhole environment model configured to simulate a downhole environment based on sensor data.

Statement 16: The non-transitory computer readable medium of preceding Statement 15 may further include the frac pump controller receiving the predicted values, and storing further instructions to adjust, based at least in part on the predicted values, a power supply level for an electric fracturing pump, the power supply level determining one or more parameters including flow rate, viscosity, or volume of a material pumped into at least one treatment fracturing well.

Statement 17: The non-transitory computer readable of any of preceding Statements 15-16 may further include the one or more downhole sensor values being received from sensors deployed in a laboratory well, the sensors including one or more of a frequency-limited pressure sensor, a distributed fiber optic temperature sensor, a strain sensor, an acoustic sensor, a microseismic sensor, or a microdeformation sensor.

Statement 18: The non-transitory computer readable of any of preceding Statements 15-17 may further include storing instructions to feed training data into a supervised learning process and change the pump control variables over a range of expected responses, the training data including frequency-limited data.

Statement 19: The non-transitory computer readable of any of preceding Statements 15-18 may further include the predicted values being provided to one of a frac pump controller or a downhole environment model at a later stage of a treatment fracturing well, and the one or more downhole sensor values being received from sensors deployed to the treatment fracturing well and at an earlier stage of the treatment fracturing well.

Statement 20: The non-transitory computer readable of any of preceding Statements 15-19 may further include storing instructions to apply the data synthesis model to one or more additional treatment fracturing wells, the data synthesis model generating additional synthetic sensor data values based on additional treatment fracturing well sensor data values, and adjust, based on the additional synthetic sensor data values, one or more additional power supplies for one or more additional fracturing pumps.

The description above includes example systems, methods, techniques, instruction sequences, and/or computer program products that embody techniques of the present disclosure. However, it is understood that the described disclosure may be practiced without these specific details.

While the present disclosure has been described with references to various implementations, it will be understood that these implementations are illustrative and that the scope of the disclosure is not limited to them. Many variations, modifications, additions, and improvements are possible. More generally, implementations in accordance with the present disclosure have been described in the context of particular implementations. Functionality may be separated or combined in blocks differently in various examples of the disclosure or described with different terminology. These and other variations, modifications, additions, and improvements may fall within the scope of the disclosure as defined in the claims that follow.

What is claimed is:

1. A computer-implemented method for generating a data synthesis model, the method comprising:
receiving one or more sensor values from one or more sensors in response to a change in pump control variables;
generating a data synthesis model configured to generate predicted values comprising one or more of the one or more sensor values based on one or more other sensor data values of the one or more sensor values and the pump control variables; and
providing the predicted values generated by the data synthesis model to one of a controller or a downhole environment model configured to simulate a downhole environment based on sensor data.

2. The method of claim 1, wherein the pump control variables comprise one or more of a surface pressure value, an acoustic sensor coupled to the wellbore fluid, one of a vibration sensor or acoustic sensor attached to the casing or tubing, a pump rate value, a chemical concentration value, a proppant rate value, a proppant ramp rate value, a diversion drop frequency value, or a diversion drop mass value;

3. The method of claim 1, wherein the frac pump controller receives the predicted values, the method further comprising adjusting, based at least in part on the predicted values, a power supply level for a frac pump, the power supply level determining one or more parameters comprising flow rate, viscosity, or volume of a material pumped into at least one treatment fracturing well.

4. The method of claim 1, wherein the one or more sensor values are received from sensors deployed in a laboratory well, including downhole sensors, the sensors comprising one or more of a frequency-limited pressure sensor, a distributed fiber optic temperature sensor, a strain sensor, an acoustic sensor, a microseismic sensor, or a microdeformation sensor.

5. The method of claim 1, further comprising feeding training data into a supervised learning process and changing the pump control variables over a range of expected responses, the training data comprising frequency-limited data.

6. The method of claim 1, further comprising feeding data into an unsupervised learning process and changing the pump control variables over a range.

7. The method of claim 1, wherein the predicted values are provided to one of a frac pump controller or a downhole environment model at a later stage of a treatment fracturing well, and the one or more downhole sensor values are received from sensors deployed to the treatment fracturing well and at an earlier stage of the treatment fracturing well.

8. The method of claim 1, further comprising:
applying the data synthesis model to one or more additional treatment fracturing wells, the data synthesis model generating additional synthetic sensor data values based on additional treatment fracturing well sensor data values; and
adjusting, based on the additional synthetic sensor data values, one or more additional power supplies for one or more additional fracturing pumps.

9. A system for generating a data synthesis model, the system comprising:
one or more processors; and
a memory comprising instructions for the one or more processors to:
receive one or more downhole sensor values from one or more downhole sensors in response to a change in pump control variables comprising one or more of a surface pressure value, a pump rate value, a chemical concentration value, a proppant rate value, a proppant ramp rate value, a diversion drop frequency value, or a diversion drop mass value;
generate a data synthesis model configured to generate predicted values comprising one or more of the one or more downhole sensor values based on one or more other sensor data values of the one or more downhole sensor values and the pump control variables; and
provide the predicted values generated by the data synthesis model to one of a frac pump controller or a downhole environment model configured to simulate a downhole environment based on sensor data.

10. The system of claim 9, wherein the frac pump controller receives the predicted values, the memory further comprising instructions to adjust, based at least in part on the predicted values, a power supply level for an electric fracturing pump, the power supply level determining one or more parameters comprising flow rate, viscosity, or volume of a material pumped into at least one treatment fracturing well.

11. The system of claim 9, wherein the one or more downhole sensor values are received from sensors deployed in a laboratory well, the sensors comprising one or more of a frequency-limited pressure sensor, a distributed fiber optic temperature sensor, a strain sensor, an acoustic sensor, a microseismic sensor, or a microdeformation sensor.

12. The system of claim 9, wherein the memory further comprises instructions to feed training data into a supervised learning process and change the pump control variables over a range of expected responses, the training data comprising frequency-limited data.

13. The system of claim 9, wherein the memory further comprises instructions to feed data into an unsupervised learning process and change the pump control variables over a range.

14. The system of claim 9, wherein the predicted values are provided to one of a frac pump controller or a downhole environment model at a later stage of a treatment fracturing well, and the one or more downhole sensor values are received from sensors deployed to the treatment fracturing well and at an earlier stage of the treatment fracturing well.

15. The system of claim 9, wherein the memory further comprises instructions to:
apply the data synthesis model to one or more additional treatment fracturing wells, the data synthesis model generating additional synthetic sensor data values based on additional treatment fracturing well sensor data values; and
adjust, based on the additional synthetic sensor data values, one or more additional power supplies for one or more additional fracturing pumps.

16. A non-transitory computer readable medium storing instructions that, when executed by one or more processors, cause the one or more processors to:
receive one or more sensor values from one or more sensors in response to a change in pump control variables;
generate a data synthesis model configured to generate predicted values comprising one or more of the one or more sensor values based on one or more other sensor data values of the one or more sensor values and the pump control variables; and
provide the predicted values generated by the data synthesis model to one of a frac pump controller or a downhole environment model configured to simulate a downhole environment based on sensor data.

17. The non-transitory computer readable medium of claim 16, wherein the pump control variables comprise one or more of a surface pressure value, a pump rate value, a chemical concentration value, a proppant rate value, a proppant ramp rate value, a diversion drop frequency value, or a diversion drop mass value.

18. The non-transitory computer readable medium of claim 16, wherein the frac pump controller receives the predicted values, and storing further instructions to adjust, based at least in part on the predicted values, a power supply level for an electric fracturing pump, the power supply level determining one or more parameters comprising flow rate, viscosity, or volume of a material pumped into at least one treatment fracturing well.

19. The non-transitory computer readable medium of claim 16, wherein the one or more downhole sensor values are received from sensors deployed in a laboratory well, the sensors comprising one or more of a frequency-limited pressure sensor, a distributed fiber optic temperature sensor, a strain sensor, an acoustic sensor, a microseismic sensor, or a microdeformation sensor.

20. The non-transitory computer readable medium of claim 16, further storing instructions to feed training data into a supervised learning process and change the pump control variables over a range of expected responses, the training data comprising frequency-limited data.
